(19) United States
(12) Patent Application Publication
(10) Pub. No.: US 2008/0092006 A1
(43) Pub. Date: Apr. 17, 2008

(54) Optimizing a Set of LBIST Patterns to Enhance Delay Fault Coverage

(76) Inventors: Nikhil Dakwala, Pflugerville, TX (US); Jonathan J. Dement, Austin, TX (US); Sang H. Dhong, Austin, TX (US); Brian Flachs, Georgetown, TX (US); Gilles Gervais, Austin, TX (US); Brad W. Michael, Cedar Park, TX (US)

Correspondence Address: DILLON & YUDELL LLP, 8911 N. CAPITAL OF TEXAS HWY.,, SUITE 2110, AUSTIN, TX, 78759, US

(21) Appl. No.: 11/533,432

(22) Filed: Sep. 20, 2006

(51) Int. Cl. G01R 31/28; G06F 11/00

(52) U.S. Cl. 714/742

(57) ABSTRACT

A method and system for mitigating the impact of voltage supply variations on logic built-in self-test (LBIST) results. The method includes, but is not limited to: creating a set of customized LBIST activation patterns during IC design; propagating the activation patterns from the scan-able latches through the non-scan latches to the device under test; propagating the data from the device under test through the non-scan latches to the scan-able latches; capturing the data in a scan-able latch; and performing each test cycle independently such that the impact of voltage supply variations between test cycles is eliminated.

### BACKGROUND OF THE INVENTION

1. Technical Field

The present invention relates in general to the field of integrated circuits (ICs). More particularly, the present invention pertains to systems and methods of logic built-in self-test (LBIST).

2. Description of the Related Art

Manufacturing integrated circuits (ICs) is a complex task. As the size and complexity of ICs increases, the chance for errors also rises. Defects can impair the performance of a circuit and in some cases may even necessitate that a circuit be scrapped. The testing of ICs thus occupies an increasing portion of the overall production process. IC testing may occur during different phases of the production process, typically during design, manufacturing, or at the end of production. Design phase tests ensure that a particular design is sound on a conceptual level. Manufacturing phase tests validate an IC's performance characteristics. End of line tests test the IC at operating speeds comparable to typical every day usage in the field.

Testing methods utilized to verify the performance of an IC may be classified as deterministic or non-deterministic. Deterministic methods apply each possible input to the IC and compare the output generated to the output expected for each input in order to determine whether the IC performs as expected. In cases where the number of possible inputs is large, the cost of deterministic testing is typically prohibitive. Non-deterministic methods apply a set of pseudorandom input patterns to the IC. The outputs are then compared to the outputs of a known-good IC that has been provided with the same set of pseudorandom input patterns. If the output values match, there is a high probability that the IC being tested operates properly. The accuracy of non-deterministic testing may thus be increased by utilizing greater numbers of input patterns and/or increasing the degree of randomness of the input patterns. Non-deterministic testing methods are typically easier and less expensive to implement than deterministic methods.

Design for test (DFT) methodologies, such as Logic built-in self-test (LBIST), seek to decrease the cost of deterministic test methods by incorporating test components into the actual design of an IC. LBIST components typically include a plurality of scan chains interposed between levels of the functional logic of an IC. Sets of test patterns may be generated and stored or scanned in the scan chains, such that a device in an IC may be ranked according to how many non-scan latches are between its input and the first scan-able latch. Test patterns may be propagated through the logic circuitry to subsequent scan chains, and the LBIST test cycle may be repeated numerous times with the corresponding results being accumulated. LBIST thus helps reduce testing costs by decreasing test-cycle duration and physical setup times.

However, LBIST test patterns also introduce noise into IC voltage supply systems. Since IC performance is variable based on voltage increases/decreases or noise introduced by the test patterns, delay faults may be erroneously detected by LBIST. The present invention thus recognizes that there is a need for an improved method and system for removing the impact of voltage supply variations from LBIST results.

### SUMMARY OF THE INVENTION

Disclosed is a method and system for mitigating the impact of voltage supply variations on logic built-in self-test (LBIST) results. In one embodiment, the method includes, but is not limited to: creating a set of customized LBIST activation patterns during IC design; propagating the activation patterns from the scan-able latches through the non-scan latches to the device under test; propagating the data from the device under test through the non-scan latches to the scan-able latches; capturing the data in a scan-able latch; and performing each test cycle independently such that the impact of voltage supply variations between test cycles is eliminated.

The above as well as additional objectives, features, and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 depicts a high level block diagram of an exemplary integrated circuit (IC) equipped with logic built-in self-test (LBIST) components, as utilized in an embodiment of the present invention;

FIG. 2 is a high level logical flowchart of an exemplary method of LBIST in accordance with one embodiment of the invention; and

FIGS. 3A-3B illustrate an example of a design of an IC, as well as a corresponding set of customized LBIST activation patterns in accordance with one embodiment of the invention.

### DETAILED DESCRIPTION OF AN ILLUSTRATIVE EMBODIMENT

The present invention provides a method and system for mitigating the impact of voltage supply variations on logic built-in self-test (LBIST) results. This mitigation is provided by creating a set of optimized LBIST activation patterns, as further described below.

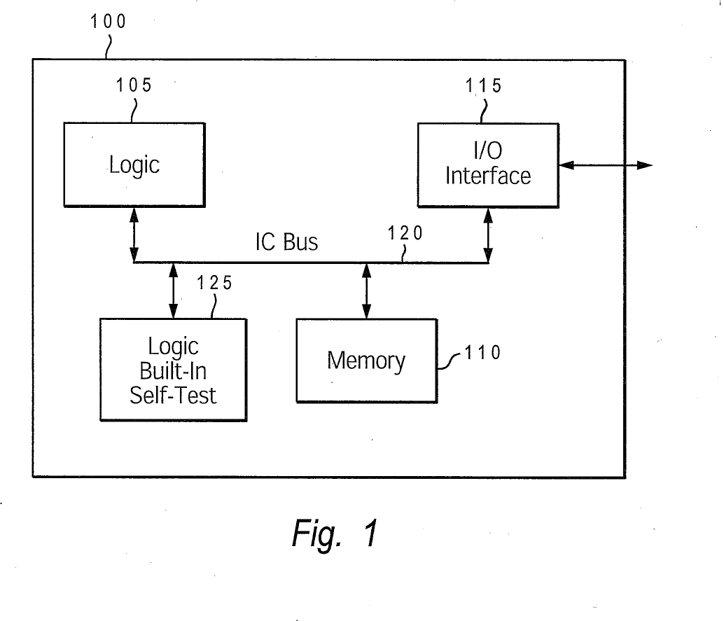

With reference now to FIG. 1, there is depicted a block diagram of an exemplary integrated circuit (IC) 100, with which the present invention may be utilized. IC 100 comprises logic 105, memory 110, input/output (I/O) interface 115, IC bus 120, and LBIST 125. Note that, as is generally the case for IC's, the specific attributes of logic 105 may vary in accordance with the desired functionality of IC 100. As shown in FIG. 1, logic 105, memory 110, I/O interface 115, and LBIST 125 may communicate internally within IC 100 via IC bus 120. In accordance with an embodiment of the invention, LBIST 125 may be utilized by the manufacturer of IC 100 to verify the functionality of logic 105 during the IC manufacturing process. Similarly, in another embodiment, LBIST 125 may be utilized by the manufacturer of IC 100 to verify the functionality of logic 105 at the conclusion of the IC manufacturing process. In yet another embodiment, LBIST 125 may be utilized by a user of IC 100 to verify the functionality of logic 105 during the use of IC 100 in the field.

FIG. 1 depicts I/O interface 115 being utilized to facilitate the communication of IC 100 with external electronic components (not shown). In an alternate embodiment of the invention, IC 100 may not include I/O interface 115. In such an embodiment, logic 105, memory 110, and/or LBIST 125 may communicate directly with external electronic components. Similarly, in another embodiment, IC 100 may not include IC bus 120. In such an embodiment, the internal components of IC 100, such as logic 105, memory 110, and LBIST 125, may be coupled directly to one another.

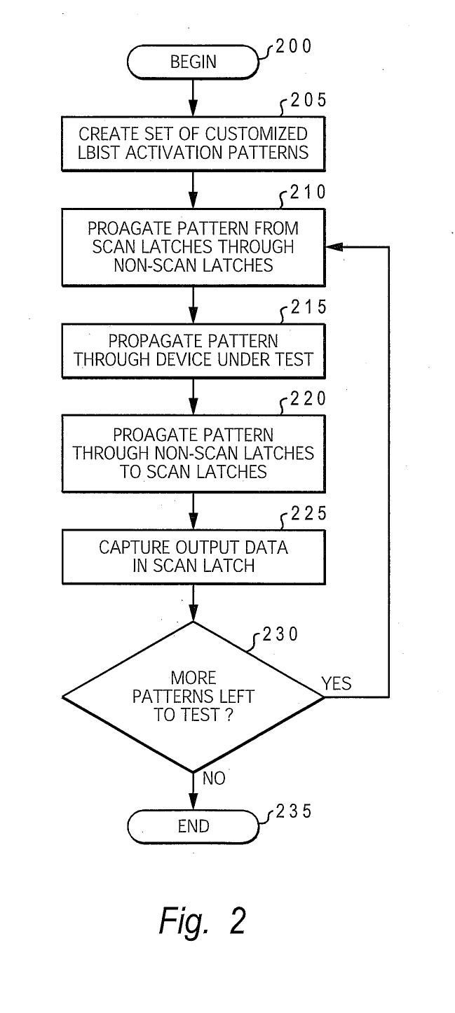

Within the descriptions of the figures, similar elements are provided similar names and reference numerals as those of the previous figure(s). Where a later figure utilizes the element in a different context or with different functionality, the element is provided a different leading numeral representative of the figure number (e.g., 1xx for FIG. 1 and 2xx for FIG. 2). The specific numerals assigned to the elements are provided solely to aid in the description and not meant to imply any limitations (structural or functional) on the invention.

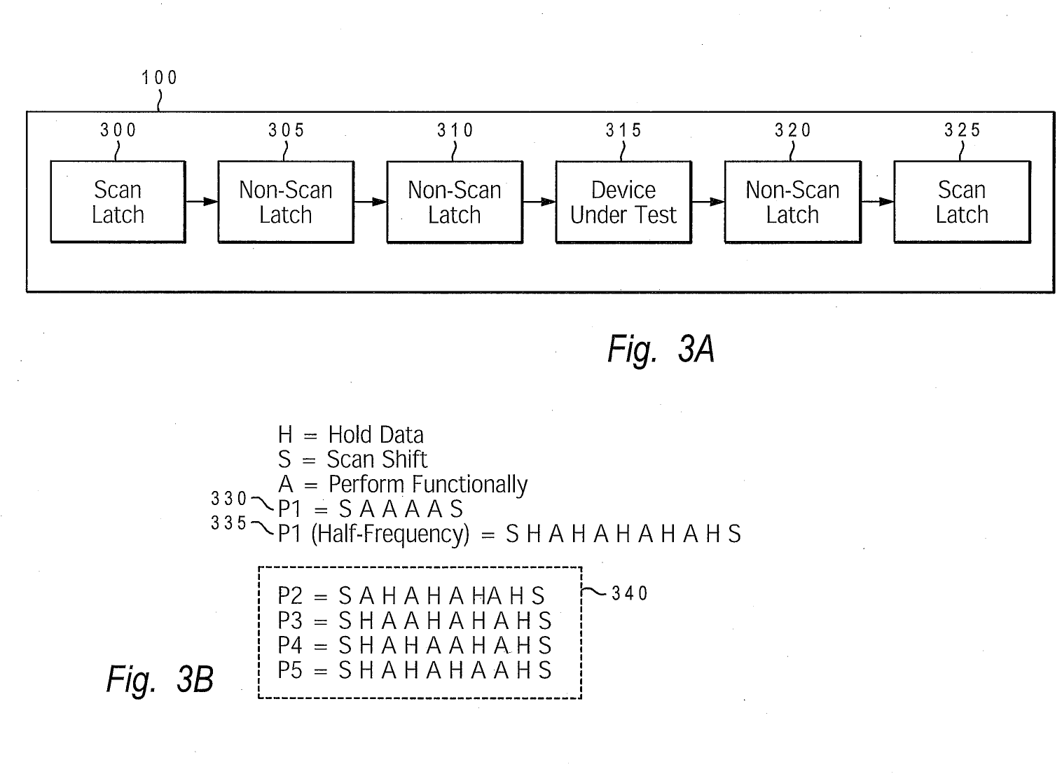

With reference now to FIG. 2, there is depicted a high level logical flowchart of an exemplary method of LBIST in accordance with one embodiment of the invention. The LBIST process begins at block 200, for example, in response to a user of IC 100 invoking LBIST 125, which preferably performs the remainder of the illustrated steps in an automated manner. At block 205, a set of customized LBIST activation patterns is created. The set of customized LBIST activation patterns comprises a number of patterns equal to the number of functional clock cycles required for bits to propagate through the components within logic 105, specifically a plurality of non-scan latches and the device under test. As utilized herein, device under test refers to any circuit, electronic component, or the like within IC 100. An example of a set of optimized LBIST activation patterns is provided in FIGS. 3A-3B and will be discussed in detail below.

Returning to FIG. 2, at block 210 the first LBIST activation pattern, from among the plurality of customized LBIST activation patterns, propagates from a plurality of scan-able latches of IC 100 through a plurality of non-scan latches within IC 100, thereby reaching the device under test. At block 215, the LBIST activation pattern propagates through the device under test, which creates output data in response to the LBIST activation pattern. At block 220, the output data propagates from the device under test through a plurality of non-scan latches within IC 100, thereby reaching a plurality of scan-able latches within IC 100. At block 225, the output data is captured in a scan-able latch.

A determination is made at block 230 whether or not additional customized LBIST activation patterns exist that have not yet been propagated through logic 105. If additional LBIST activation patterns, from among the plurality of customized LBIST activation patterns created at block 205, exist, then the process returns to block 210 and propagates the next LBIST activation pattern through logic 105. If no additional LBIST activation patterns exist, then the process terminates at block 235. A user may then utilize the output data to determine whether IC 100 contains any delay faults and also to determine the location within IC 100 of any delay faults that may exist, as further described below.

With reference to FIG. 3A, there is illustrated an example of a IC design comprising scan-able latches, non-scan latches, and a device under test in accordance with one embodiment of the invention. As shown in FIG. 3A, IC 100 includes scan-able latch 300, non-scan latch 305, non-scan latch 310, device under test 315, non-scan latch 320, and scan-able latch 325. Although FIG. 3A depicts IC 100 as including three non-scan latches 305, 310, 320, IC 100 may instead contain zero non-scan latches. Similarly, in another embodiment, IC 100 may contain a different number than three of non-scan latches. In order for device under test 315 to be tested by an LBIST activation pattern, the LBIST activation pattern must propagate from scan-able latch 300 to scan-able latch 325 by propagating through three non-scan latches 305, 310, 320 and device under test 315.

Turning now to FIG. 3B, there is illustrated an example of optimizing LBIST activation patterns in accordance with one embodiment of the invention. FIG. 3B comprises original activation pattern 330, half-frequency activation pattern 335, and a plurality of customized patterns 340. The plurality of customized activation patterns 340 comprises four separate activation patterns as follows: P2=SAHAHAHAHS; P3=SHAAHAHAHS; P4=SHAHAAHAHS; and P5=SHAHAHAAHS. As shown in FIG. 3B, LBIST activation patterns may be defined by a plurality of different instruction bits including, but not limited to, the following: H=Hold Data; S=Scan Shift; and A=Perform Functionally. As depicted in FIG. 3A, IC 100 comprises three non-scan latches 305, 310, 320, and one device under test 315. Original activation pattern 330 must thus include four A bits, as depicted in FIG. 3B, in order to test the functionality of each entity on the path between scan-able latch 300 and scan-able latch 325.

Generally, the bits in an LBIST activation pattern may be arranged in a plurality of orders, with H bits being utilized to vary the timing of the performance prompts caused by the A bits in relation to a clock signal. For example, in FIG. 3B, half-frequency activation pattern 335 contains four A bits, each separated by a single H bit. Half-frequency activation pattern thus performs the same functional tests as original activation pattern 330, but at half the frequency of original activation pattern 330 as compared to the clock signal within IC 100. The performance of IC 100 can thus be verified at multiple operational frequencies, according to the combination of bits used within an LBIST activation pattern.

Both S and A bits cause some nodes within IC 100 to switch states. State changes cause current to flow, which in turn leads to variations in the supply voltage of devices within IC 100. These supply voltage variations cause circuit performance to speed up in when supply voltage is high and/or to slow down when supply voltage is low. Thus, if device under test 315 is susceptible to a speed fault and is tested during a clock cycle when the supply voltage at device under test 315 is high, then device under test 315 may erroneously appear to be faster than a properly manufactured device. Similarly, if device under test 315 is susceptible to a speed fault and is tested during a clock cycle when the supply voltage at device under test 315 is low, then device under test 315 may erroneously appear to be slower than a properly manufactured device. The speed faults described above may be undetectable by conventional LBIST methods. The present invention thus studies the performance of each component in the path between scan-able latch 300 and scan-able latch 325 independently, via the utilization of the plurality of customized activation patterns 340, each of which corresponds to a specific component in the path between scan-able latch 300 and scan-able latch 325.

According to the invention, as applied to IC 100 or FIG. 3A, activation pattern P2 tests the launch from scan-able latch 300 to non-scan latch 305. Activation pattern P3 tests the path from non-scan latch 305 to non-scan latch 310. Activation pattern P4 tests the path from non-scan latch 310 to non-scan latch 320, which includes device under test 315. Activation pattern P5 tests the path from non-scan latch 320 to scan-able latch 325. If device under test 315 does not contain a delay fault, then each of the plurality of customized activation patterns 340 produces the same output data as original activation pattern 330 (i.e. P1 Output=P2 Output=P3 Output=P4 Output=P5 Output).

Each of the plurality of customized activation patterns 340 has a different characteristic voltage versus frequency relationship, which represents the first failure for a nominally manufactured IC. This voltage versus frequency relationship may be characterized by the expression Vmin/Fmax. The occurrence of delay faults causes a deviation from this characteristic Vmin/Fmax. Furthermore, the Vmin/Fmax of each of the plurality of customized activation patterns 340 may serve as a measure of both the structure of the devices present within IC 100 and any variations in supply voltage that may occur during LBIST. Consequently, if device under test does contain a delay fault, the origin of the delay fault may be determined by comparing the Vmin/Fmax observed during LBIST to the characteristic Vmin/Fmax of device under test 315. The present invention thus utilizes the characteristic Vmin/Fmax of devices within IC 100 to mitigate the impact of voltage supply variations between test cycles, which may otherwise occur in present LBIST methods.

It is understood that the use herein of specific names are for example only and not meant to imply any limitations on the invention. The invention may thus be implemented with different nomenclature/terminology and associated functionality utilized to describe the above devices/utility, etc., without limitation.

While the invention has been particularly shown and described with reference to a preferred embodiment, it will be understood by those skilled in the art that various changes in form and detail may be made therein without departing from the spirit and scope of the invention.

What is claimed is:

1. An integrated circuit (IC) comprising:
a functional logic having a plurality of latches, including at least two scan-able latches, and a device under test (DUT), wherein said function logic exhibits specific operating characteristics; and
testing logic for enabling verification, via the LBIST, of the functionality of functional logic at one or more periods from among (a) during a manufacture of the IC manufacturing process, (b) after the manufacture of the IC, and (c) during post manufacture utilization of the IC, said testing logic including logic for:
initiating a propagation of a first LBIST activation pattern from among the one or more customized LBIST activation patterns, whereby the first LBIST activation pattern propagates from one or more scan-able latches to the DUT;
propagating the first LBIST activation pattern through the DUT to generate output data in response to the customized LBIST activation pattern;
forwarding the output data from the DUT through one or more scan-able latches;
holding the output data within one of said one or more scan-able latches.
sequentially propagating each of the remaining customizable LBIST activation patterns through the logic similarly to the first LBIST activation pattern and collecting generated output data within different ones of the one or more scan-able latches;
wherein the output data generated and collected within the scan-able latches enables a determination of whether the IC contains any delay faults and a location of any delay faults that exists within the DUT and the IC;
wherein, when the DUT does not contain a delay fault, each of the one or more customized LBIST activation patterns produces a same output data as an original activation pattern.

2. The IC of claim 1, wherein:
the functional logic is configured with a sequence of components that include the DUT preceded by at least one first scan-able latch and followed by at least one second scan-able latch; and
said customized LBIST activation patterns comprises a number of patterns equal to the number of functional clock cycles required for bits to propagate through components within the functional logic.

3. The IC of claim 2, wherein:
the functional logic further comprises at least one non-scan latch preceding and/or following the DUT;
the customized LBIST activation patterns are designed based on the number of components within the functional logic; and said testing logic comprises logic for:
propagating the first LBIST activation pattern from one or more scan-able latches through one or more non-scan latches to the DUT; and
forwarding the output data from the DUT through one or more non-scan latches to one or more scan-able latches.

4. The IC of claim 1, wherein:
LBIST activation patterns provided for said testing logic include patterns from among: original activation patterns, half-frequency activation patterns, and the one or more customized LBIST activation patterns; and
the LBIST activation patterns are defined by a plurality of different instruction bits, such as: H=Hold Data; S=Scan Shift; and A=Perform Functionally;
wherein further H bits are utilized to vary the timing of the performance prompts caused by the A bits in relation to a clock signal, to enable the performance of the IC to be verified at multiple operational frequencies, according to the sequence combination of bits utilized within an LBIST activation pattern; and
wherein said S bits and said A bits cause nodes within the IC to switch states, which results in variations in the supply voltage of the devices within the IC, and changes in a speed of circuit performance.

5. The IC of claim 1, wherein each of the plurality of customized activation patterns corresponds to a specific component in the path between a first scan-able latch and a last scan-able latch, and utilization of the customizable LBIST activation patterns within the IC enables independent study of a performance of each component in the propagating path between the first scan-able latch and the last scan-able latch independently, without consideration for changes in the supply voltage of the devices due to the S bits and A bits propagating through the IC.

6. The IC of claim 1, said testing logic for enabling verification of the functional logic further comprises logic for:
coupling an external electronic component to the IC;
receiving an input to initiate LBIST on the circuit; and
automatically generating a pre-established set of customized LBIST activation patterns.

7. The IC of claim 6, further comprising:
an input/output (IO) interface; and
wherein said logic for coupling couples the external electronic component to the IC via the IO interface.

8. The IC of claim 1, further comprising:
a memory component; and
an IC bus, wherein said logic and said memory and said plurality of latches are coupled together via said IC bus.

9. A method for mitigating the impact of voltage supply variations on results of logic built-in self-test (LBIST) in an integrated circuit (IC) having:
a functional logic including a device under test (DUT), wherein said function logic exhibits specific operating characteristics;
a memory component coupled to the functional logic; and
testing logic for enabling verification, via a logic built-in self test (LBIST), of the functionality of the functional logic at one or more periods from among (a) during a manufacture of the IC manufacturing process, (b) after the manufacture of the IC, and (c) during post manufacture utilization of the IC, said testing logic having a plurality of latches, including at least two scan-able latches, interposed around the DUT;
said method comprising:
initiating a propagation of a first LBIST activation pattern from among the one or more customized LBIST activation patterns, whereby the first LBIST activation pattern propagates from one or more scan-able latches to the DUT;
propagating the first LBIST activation pattern through the DUT to generate output data in response to the customized LBIST activation pattern;
forwarding the output data from the DUT through one or more scan-able latches;
holding the output data within one of said one or more scan-able latches.
sequentially propagating each of the remaining customizable LBIST activation patterns through the logic similarly to the first LBIST activation pattern and collecting generated output data within different ones of the one or more scan-able latches;
wherein the output data generated and collected within the scan-able latches enables a determination of whether the IC contains any delay faults and a location of any delay faults that exists within the DUT and the IC;
wherein, when the DUT does not contain a delay fault, each of the one or more customized LBIST activation patterns produces a same output data as an original activation pattern.

10. The method of claim 9, wherein:
the functional logic is configured with a sequence of components that include the DUT preceded by at least one first scan-able latch and followed by at least one second scan-able latch; and
said customized LBIST activation patterns comprises a number of patterns equal to the number of functional clock cycles required for bits to propagate through components within the functional logic.

11. The method of claim 10, wherein:
the functional logic further comprises at least one non-scan latch preceding and/or following the DUT;
the customized LBIST activation patterns are designed based on the number of components within the functional logic; and
said method further comprises:
propagating the first LBIST activation pattern from one or more scan-able latches through one or more non-scan latches to the DUT; and
forwarding the output data from the DUT through one or more non-scan latches to one or more scan-able latches.

12. The method of claim 9, wherein:
LBIST activation patterns provided for said testing logic include patterns from among: original activation patterns, half-frequency activation patterns, and the one or more customized LBIST activation patterns; and
the LBIST activation patterns are defined by a plurality of different instruction bits, such as: H=Hold Data; S=Scan Shift; and A=Perform Functionally;
wherein further H bits are utilized to vary the timing of the performance prompts caused by the A bits in relation to a clock signal, to enable the performance of the IC to be verified at multiple operational frequencies, according to the sequence combination of bits utilized within an LBIST activation pattern; and
wherein said S bits and said A bits cause nodes within the IC to switch states, which results in variations in the supply voltage of the devices within the IC, and changes in a speed of circuit performance.

13. The method of claim 9, wherein each of the plurality of customized activation patterns corresponds to a specific component in the path between a first scan-able latch and a last scan-able latch, and utilization of the customizable LBIST activation patterns within the IC enables independent study of a performance of each component in the propagating path between the first scan-able latch and the last scan-able latch independently, without consideration for changes in the supply voltage of the devices due to the S bits and A bits propagating through the IC.

14. The method of claim 9, wherein said enabling verification of the functional logic further comprises:
coupling an external electronic component to the IC;
receiving an input to initiate LBIST on the circuit; and
automatically generating a pre-established set of customized LBIST activation patterns.

15. The method of claim 14, wherein said IC further comprises an input/output (IO) interface, and said coupling couples the external electronic component to the IC via the IO interface.

16. A system comprising:
one or more latches from including at least a plurality of scan-able latches;
a device under test (DUT), which exhibits specific operating characteristics.
a logic built-in self test (LBIST) designed based on the characteristics and attributes of the one or more latches and the DUT, said LBIST including customized LBIST activation patterns having a number of patterns equal to the number of functional clock cycles required for bits to propagate through the one or more latches and the DUT.
means for enabling verification, via the LBIST, of the functionality of functional logic at one or more periods from among (a) during a manufacture of the IC manufacturing process, (b) after the manufacture of the IC, and (c) during post manufacture utilization of the IC, said means including means for:
initiating a propagation of a first LBIST activation pattern from among the one or more customized LBIST activation patterns, whereby the first LBIST activation pattern propagates from one or more scan-able latches to the DUT;
propagating the first LBIST activation pattern through the DUT to generate output data in response to the customized LBIST activation pattern;
forwarding the output data from the DUT through one or more scan-able latches;
holding the output data within one of said one or more scan-able latches.
sequentially propagating each of the remaining customizable LBIST activation patterns through the logic similarly to the first LBIST activation pattern and collecting generated output data within different ones of the one or more scan-able latches;
wherein the output data generated and collected within the scan-able latches enables a determination of whether the IC contains any delay faults and a location of any delay faults that exists within the DUT and the IC;
wherein, when the DUT does not contain a delay fault, each of the one or more customized LBIST activation patterns produces a same output data as an original activation pattern.

17. The system of claim 16, wherein:
the DUT is preceded by at least one first scan-able latch and followed by at least one second scan-able latch; and
when the system further comprises at least one non-scan latch preceding and/or following the DUT;
the customized LBIST activation patterns are designed based on the total number of components, such that the means comprises means for:
propagating the first LBIST activation pattern from one or more scan-able latches through one or more non-scan latches to the DUT; and
forwarding the output data from the DUT through one or more non-scan latches to one or more scan-able latches.

18. The system of claim 16, wherein:
LBIST activation patterns provided for said testing logic include patterns from among: original activation patterns, half-frequency activation patterns, and the one or more customized LBIST activation patterns; and
the LBIST activation patterns are defined by a plurality of different instruction bits, such as: H=Hold Data; S=Scan Shift; and A=Perform Functionally;
wherein further H bits are utilized to vary the timing of the performance prompts caused by the A bits in relation to a clock signal, to enable the performance of the IC to be verified at multiple operational frequencies, according to the sequence combination of bits utilized within an LBIST activation pattern; and
wherein said S bits and said A bits cause nodes within the IC to switch states, which results in variations in the supply voltage of the devices within the IC, and changes in a speed of circuit performance.

19. The system of claim 16, wherein each of the plurality of customized activation patterns corresponds to a specific component in the path between a first scan-able latch and a last scan-able latch, and utilization of the customizable LBIST activation patterns within the IC enables independent study of a performance of each component in the propagating path between the first scan-able latch and the last scan-able latch independently, without consideration for changes in the supply voltage of the devices due to the S bits and A bits propagating through the IC.

20. The IC of claim 1, further comprising:
an input/output (IO) interface; and
said means for enabling verification of the functional logic further comprises means for:
coupling an external electronic component to the IC via the IO interface;
receiving an input to initiate LBIST on the circuit; and
automatically generating a pre-established set of customized LBIST activation patterns.
